(19) United States
(12) Patent Application Publication
(10) Pub. No.: US 2006/0201709 A1
(43) Pub. Date: Sep. 14, 2006

(54) Low profile small outline leadless semiconductor device package

(76) Inventor: Chandler H. McIver, Temple, AZ (US)

Correspondence Address: WILLIAM C. CAHILL, 155 PARK ONE, 2141 E. HIGHLAND AVENUE, PHOENIX, AZ, 85016, US

(21) Appl. No.: 10/552,186

(22) PCT Filed: Apr. 7, 2004
(86) PCT No.: PCT/US04/10679

§ 371 Date: Oct. 6, 2005

Related U.S. Application Data
(60) Provisional application No. 60/461,122, filed on Apr. 7, 2003.

(51) Int. Cl. H01L 23/28

(52) U.S. Cl. 174/521

(57) ABSTRACT

A molded leadless package encapsulates a small outline integrated circuit or small outline transistor through contact bumps. Electrical contacts extend from the encapsulated device to an exposed surface of the package and are coplanar with that surface and terminate at a junction between said surface at a junction with another of the package surfaces. The contacts terminate only at oppositely disposed surfaces of the package.

### FIELD OF THE INVENTION

The present invention relates to semiconductor packaging, and more particularly to the encapsulation of solderable circuit devices to provide a package with minimum size to facilitate incorporation into electronic systems.

### BACKGROUND OF THE INVENTION

The history of semiconductor development has been one of continuously striving for smaller and smaller devices and the packages that house those devices. For most of the uses and applications of semiconductor devices, some type of protective package is required to not only protect the device from various environments, but also to allow for handling and assembly into the next level of the electronic system. The history of semiconductor device packaging has paralleled the development of semiconductor devices with the need to reduce the size of the package as the size of the device it houses is reduced. The technology to house most semiconductor devices was the chip-and-wire technique.

A prior art technology used to house most semiconductor devices incorporates a semiconductor device or chip attached to a lead using industry standard electrically conductive attachment materials. A wire is then attached to another portion of the device and to another lead of the package.

This same concept has been extended to semiconductor devices with multiple leads using multiple wires to connect to multiple leads. A variety of industry standard packages have been established over the history of the semiconductor industry with the major variations pertaining to how the leads of the packages were configured after they exit the body of the molded package. Initially the leads were configured so that they were inserted into holes in the next level substrate to form an electronic system. This was designated as through-hole technology and required the use of drilled and plated substrates, which were expensive and could only handle packages where the leads were widely separated.

A variation to the chip and wire technology was developed early to house discrete semiconductor devices, transistor and diodes. These discrete devices had solderable contacts on both sides of the device and were then soldered into what is referred to as an axial leaded device where the leads of the package extended in an axial direction away from the discrete semiconductor device. This package was similar to that used for resistors and capacitors where the axial leads were then formed and inserted into the holes of the next level substrate using the technology call through-hole assembly.

The next development was referred to as surface-mount technology wherein a package was mounted on the top of a substrate thus eliminating the need to drill holes in the substrate and thereby reducing cost; this technique permitted the spacing between leads to be reduced leading to small packages and smaller electronic systems. Such surface mounted systems facilitate the design and manufacture of portable handheld systems such as cell phones, portable computers and various other electronic systems for the benefit consumers. Another advantage of the surface mount technology was the ability to mount components on both sides of the substrate leading to further reductions in the system size.

The makers of electronic systems continue to push the manufacturers of semiconductor devices to supply smaller and smaller packages because of the competitive advantage to the maker of the electronic system. The smaller that the maker of the system can make the product, the more attractive it is to the consumer and the lower the cost.

This push to smaller and smaller semiconductor device packages has lead to a major shift in some semiconductor packaging where the chip-and-wire technology is replaced with a technology called flip chip. Using this technology, conductive solder bumps are placed on the electrically active top surface only of the semiconductor device and then the device or chip is flipped upside down to be mounted in a package or on a substrate. This technology eliminates the wires used to connect the active portions of the top surface of the semiconductor device to the leads of a package and can lead to smaller and smaller packages.

The flip chip technology was adopted by the manufacturers of integrated circuit devices where the packages and the semiconductor device or chip are larger with many leads. There are few packages designed specifically for the flip chip technology and those that are designed for flip chip technology are designed for integrated circuit semiconductor devices. Such a package is illustrated in U.S. Pat. No. 6,507,120, which specifically addresses a flip chip quad package, which means that the resulting package has leads along the periphery of all four sides of that package. This structure is necessary to accommodate all of the contacts of the integrated circuit device, but is too large and expensive for discrete devices with very few contacts.

Because discrete semiconductor devices have only two or three contacts, they require fewer leads than the integrated circuit semiconductor devices with these leads located at only two opposite sides of a four-sided package. The push for smaller and smaller packages has impacted the discrete semiconductor devices as well as the integrated circuit semiconductor devices. One particular group of such small packages is referred to in the industry as small outline packages. There are both small outline integrated circuit (SOIC) and small outline transistor (SOT) packages in wide use throughout the microelectronics field. These packages are characterized by a small molded body with very short leads extending from that body where the leads are used to contact the substrate used in the next level of assembly which is the surface mount technology. The package body is molded around the semiconductor device, which is attached to the leads of the package. The package leads serve to provide electrical connection from the semiconductor device to the rest of the electrical system where that semiconductor device is utilized while the molded housing provides mechanical protection along with protection from possible corrosive elements that could impact the semiconductor device.

One of the advantages of a diode or transistor, specifically diodes, is that the diode can be manufactured so that one of the electrical contacts is on the bottom of the diode with the other electrical contact on the top or opposite side of the diode. In a similar way, a transistor can be manufactured with one electrical contact on one side of the transistor with the other two required electrical contacts on the opposite side of the transistor device. This type of device structure has been used for many years to produce axial leaded packages. There is no such related package for discrete devices with electrical contacts on both sides of the device to be used in the surface mount technology.

Improvements in package materials and manufacturing machinery along with manufacturing process improvements have enabled the semiconductor packaging industry to continue to make smaller and smaller packages to accommodate the needs of the electronic system manufacturer. The problem now in the industry, particularly with the diode and transistor semiconductor devices is the height of the resulting rectangular packages. The industry has made the length and width of the packages so small that the height of the package approaches or even exceeds either the length or width of that same package. The resulting package looks almost like a miniature cube and is unstable in handling after the package manufacturing is completed.

A key element is handling such small packages it the development of the tape and reel handling system wherein a narrow tape has sprockets holes formed along one or both sides and a pocket formed in the middle of the tape that is sized to accept one of the small packages. Packages are loaded into this tape following assembly and test and the tapes are formed into reels of product, which is then shipped to be used for assembly into an electronic system. Loading of the very small packages, where the height is greater than or equal to the length and width of that package is more difficult with greater losses, slower machine operating rates and higher costs. Once the reel of packaged semiconductor devices is received for assembly into electronic systems where the devices are unloaded from the reel, the same type of problems are encountered again thus raising the cost and slowing the process.

Another problem encountered with many of the small outline packages are the leads extending beyond the body of the package. These leads can catch in the pocket formed in the tape, which makes them very difficult to unload at the final assembly step where the semiconductor device is assembled into the electronic system. Again, the situation exists where the machine rate is decreased, the losses increase and the costs increase.

### SUMMARY OF THE INVENTION

The present invention is a very low profile, small outline, and leadless molded package for discrete solderable semiconductor devices with contact leads on only two opposite areas on the bottom of the package. The resulting package is more stable than previous discrete semiconductor packages and can be used with discrete devices that have solderable contacts on one side of that device or on both sides of a discrete semiconductor device. No current rectangular surface mount package is available to accommodate a discrete semiconductor device with contacts on both sides of that device.

One embodiment of this invention also provides improved mechanical strength of the molded package by creating specially designed notches in the conductive contacts of the package so that the molding material can flow around those conductive contacts forming a much stronger mechanical bond between the mold material and the package contact pads resulting in higher mechanical integrity and better protection from corrosive environments. This conductive contact structure is designed to eliminate delamination between the contact and the plastic molding compound during subsequent manufacturing steps and to provide a more reliable package for the next level assembly. Other embodiments use other conductive contact configurations to achieve better mechanical strength in the resulting molded package.

The invention provides a low cost package with very little wasted material in view of the fact that the packages are manufactured in large arrays with the individual packages then created by cutting apart the arrays, testing the units and then packaging and shipping the completed devices. This assembly technique minimizes the amount of conductive contact material and plastic molding compound needed for manufacturing and thereby minimizes the resulting manufacturing cost.

This invention also provides contact pads in the body of the molded package that do not extend beyond the edges of the molded package thereby making the overall package dimensions smaller and eliminating the handling problem associated with leads that extend beyond the edge of a package where such extended leads can catch on shipping material like tapes and/or reels causing losses and increased cost. The invention can provide unique shapes for one or more of the exposed contact pads on the molded package to help identify critical contact pads of the molded package for proper installation into the next level of assembly. Such unique contact pad shapes allow for the use of industry standard visual inspection systems coupled with automatic pick and place systems for rapid and low cost incorporation into the next level of assembly.

Since this invention utilizes solderable semiconductor device manufacturing exclusively, it can create a molded package that is much smaller than a similar package designed to accommodate the usual chip and wire assembly technology. An alternate benefit of this invention is the ability to place a larger flip chip semiconductor device into a given package with specified length and width than the chip and wire semiconductor device being assembled into that same specified package. The result is a packaged device with improved electrical performance when compared to the chip and wire device. This small package is more stable and provides easier handling after the package is manufactured.

The invention can use a variety of shapes of the conductive leads molded within the package body which then allow this invention to be used for discrete semiconductor devices with solderable contacts on both surfaces of the discrete device or with the solderable contacts all on one surface of the discrete device. The invention greatly reduces overall dimensions compared to packages established for a chip and wire assembly; no leads extend beyond the body of the package compared to most small outline packages which thus provide improved handling following manufacturing of the invention and thereby reduces the cost associated with such handling.

### BRIEF DESCRIPTION OF THE DRAWINGS

The accompanying drawings are included to provide further understanding of this invention and are a part of this specification. The drawings illustrate embodiments of this invention and help explain the principle of the invention. In the drawings,

FIG. 1 is a side elevational view, partly in section, of the prior art of chip and wire assembly;

FIG. 2 is a side elevational view, partly in section, of one embodiment of the present invention showing a two leaded package configuration;

FIG. 3 is a bottom view of the package illustrated in FIG. 2;

FIG. 4 is a top view of the package illustrated in FIG. 2;

FIG. 5 is a view to illustrate the notch in the lead frame of the package of this invention.

FIG. 6 is a side elevational view, partly in section, of another embodiment of the present invention;

FIG. 7 is a side elevational view, partly in section, of still another embodiment of the present invention;

FIG. 8 is a side elevational view, partly in section, of another embodiment of the present invention utilizing contact on both side of the semiconductor device;

FIG. 9 is a side elevational view, partly in section, of another embodiment of the present invention where the semiconductor device is mounted in a vertical configuration;

FIG. 10 is a side elevational view, partly in section, of still another embodiment of the present invention.

### DESCRIPTION OF THE PREFERRED EMBODIMENT

Prior art technology used to house most semiconductor devices in a manner illustrated in the partial cross-sectional view of FIG. 1. In this technology a semiconductor device or chip 12 is attached to a lead 11 of a molded package 10 using industry standard electrically conductive attachment materials 14. A wire 13 is then attached the other portion 15 of the device and to another lead 16 of the package 10. The package 10 illustrated in FIG. 1 is for a two-lead semiconductor device.

Referring now to FIGS. 2, 3, and 4, a semiconductor device 23 is shown with a solder contact bump 24 formed on one portion of the semiconductor device and a second solder contact bump 31 formed on another portion of the semiconductor device using industry standard techniques. Also using industry standard techniques the semiconductor device 23 is assembled with the contact bump 24 attached to a lead or conductor 21 at an upper surface 28 of the lead 21 while the contact bump 31 is simultaneously attached at an upper surface 30 of contact 29. Package material 20 is then molded around the semiconductor device 23 and around the leads 21 and 29 stopping at a surface 22 that is co-planar with the lower surfaces 27 and 32 of the conductors 21 and 29 respectively. The package extends above a top surface 33 of the semiconductor device 23, extends beyond an edge 34 of the semiconductor device 23, extends beyond a second edge 35 of the semiconductor device 23, extends beyond a third edge 36 of the semiconductor device 23 and further extends beyond a fourth edge 37 of the semiconductor device 23. The package is thus provided with a top, bottom and side surfaces with the exposed lead contact surfaces 27 and 32 coplanar with the bottom surface 22 of the package. The contact surfaces 27 and 32 terminate at the junction between the corresponding bottom surface 22 of the package and one of the side surfaces thereof. It should be noted that the termination of the contacts occurs only at oppositely disposed side surfaces of the package. That is, the packages are axial leaded discrete device packages.

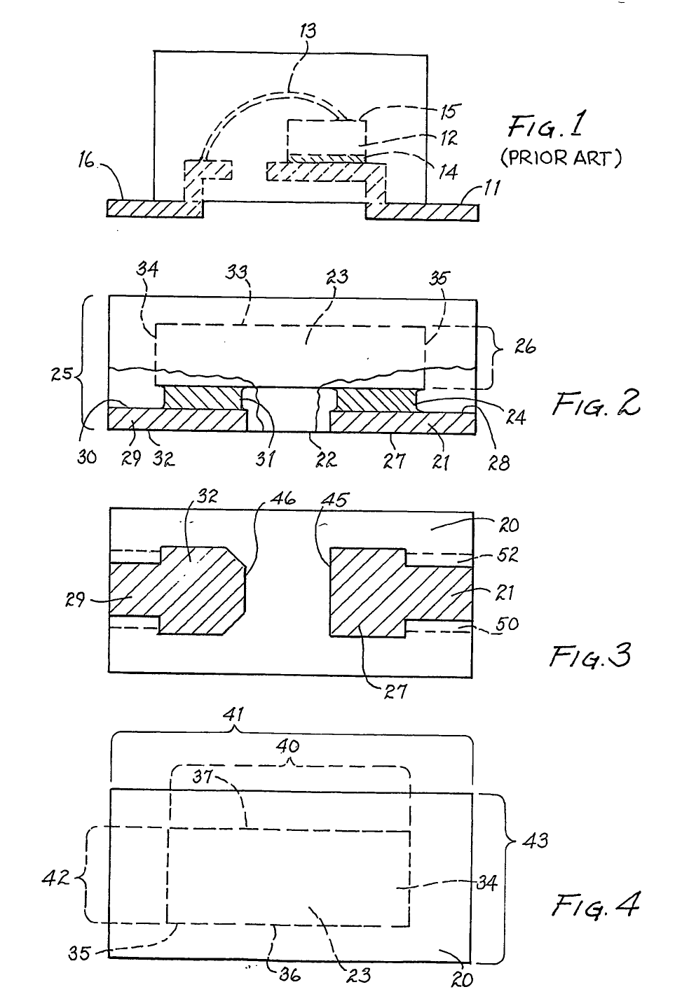

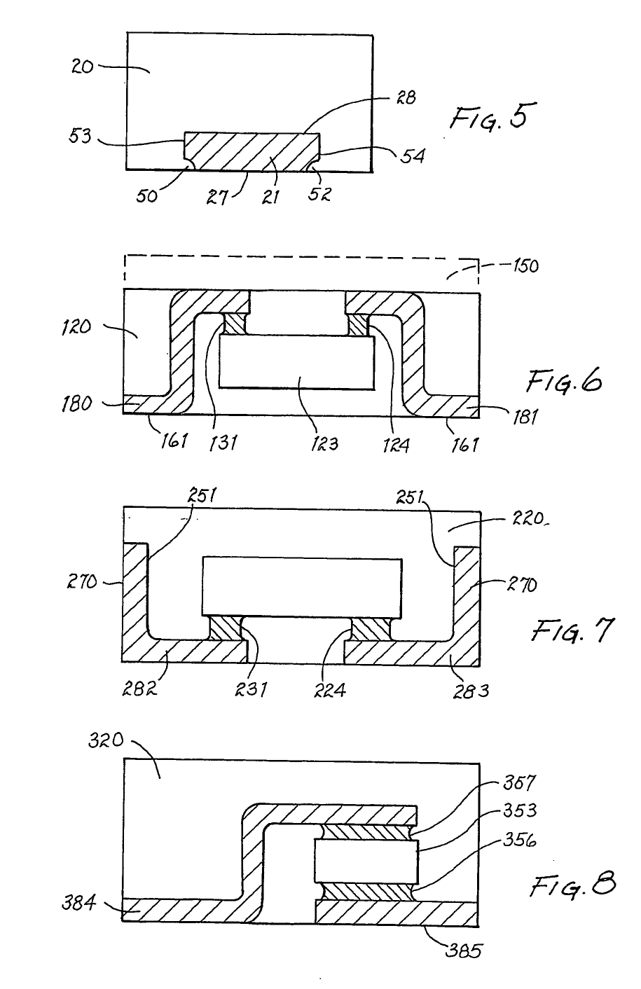

The lead 21 is formed as illustrated in FIG. 5 with an elongated notch 50 extending from the bottom surface 27 of the lead 21 to a side 53 of the lead 21 with a second notch 52 extending from the bottom surface 27 of the lead 21 to an opposite side 54 of the lead. The notches 50 and 52 can use various geometries and provide, for the molded package 20, improved mechanical attachment to the lead 21. The lead 29 is provided with similar longitudinally extending notches in the same manner with the same resulting improved mechanical attachment to the molded package 20. The heads of the leads 21 and 29 are also enlarged as shown in FIG. 3 at 45 and 46 respectively. When encased in the package material, the enlarged heads together with the longitudinally extending notches lock the conductors in place and prevent motion relative to the package. The enlarged heads may be formed into shapes that assist in the identification of the electrical function of the device; for example, the conductors or leads 21 and 29 have enlarged heads that indicate that the device in the package is a diode and has a particular polarity. Further, the use of a notch in the lead structure gives improved mechanical strength and resistance to corrosive elements thereby improving the reliability of any product produced with this invention. Following the molding operation, any excess material used as part of the industry standard assembly and manufacturing process is removed.

The preferred embodiment of the invention results in high packing density where the overall dimensions of the package 20 are minimally greater than the overall dimensions of the semiconductor device 23. Specifically as illustrated in FIG. 2, the height 25 of the molded package 20 is no greater than 0.014 inches more than the height 26 of the semiconductor device 23. As illustrated in FIG. 4, the length of the molded package 20 is no greater than 0.011 inches more than the length 40 of the semiconductor device 23 while width 43 is no greater than 0.011 inches more than the width 42 of the semiconductor device 23.

In another embodiment of the invention illustrated in FIG. 6, the lead frame 180 and the lead frame 181 are formed in a S-shape as shown and the semiconductor device 123 is solder attached through solder contact bump 131 to lead frame 180 and is attached to lead frame 181 through solder contact bump 124 using industry standard techniques. One advantage of this configuration is that the conductive contact pads 160 and 161 of the resulting molded package 120 can be on exposed on the opposite sides of the package 120. As an option, the package 120 can be over-molded as shown at 150 to cover contact pads 160. Other elements of the preferred embodiment such as the shape of the contact pads 161 on the bottom of the package 120 can be selected in a manner similar to the preferred embodiment.

In another embodiment of the invention illustrated in FIG. 7 wherein the lead frame 282 and the lead frame 283 are formed in a L-shape as shown and the semiconductor device 223 is solder attached using solder contact bump 231 attached to lead frame 282 and solder bump 224 attached to lead frame 283 using industry standard techniques. The advantage of this configuration is that contact areas 270 of the lead frames 282 and 283 can be on both the bottoms of the molded package 220 and the opposite ends of that package 220.

Another embodiment of the invention is illustrated in FIG. 8 wherein a different semiconductor device 353 is solder attached using a solder bump 356 attached to lead frame 385 and a second solder bump 357 attached to lead frame 384 using industry standard techniques. Semiconductor device 353 is manufactured with solder bump 357 on one side of the semiconductor device 353 and solder bump 356 on the opposite side of the semiconductor device 353. Lead frame 384 and lead frame 385 are formed in the shape shown in FIG. 8 and the molded package 320 then formed as shown.

Another embodiment of the invention is illustrated in FIG. 9 wherein semiconductor device 453 is mounted vertically in the molded package 20. Lead frame 486 and lead frame 487 are formed as shown in FIG. 9. An area 451 that will not solder is formed on lead frame 486 and lead frame 487. Such an area 451 can be formed using a variety of industry standard techniques with coatings referred to as “solder resists” or selective plating of metals that are then oxidized and form the selected areas that will not solder. When semiconductor device 453 is attached with solder bump 457 soldered to lead frame 487 and solder bump 456 soldered to lead frame 486, the semiconductor device 453 is aligned with lead frame 486 by the flow of solder bump 457 to a solderable area 475 of lead frame 486 and is aligned with lead frame 487 by the flow of solder bump 456 to a solderable area 475 of lead frame 487.

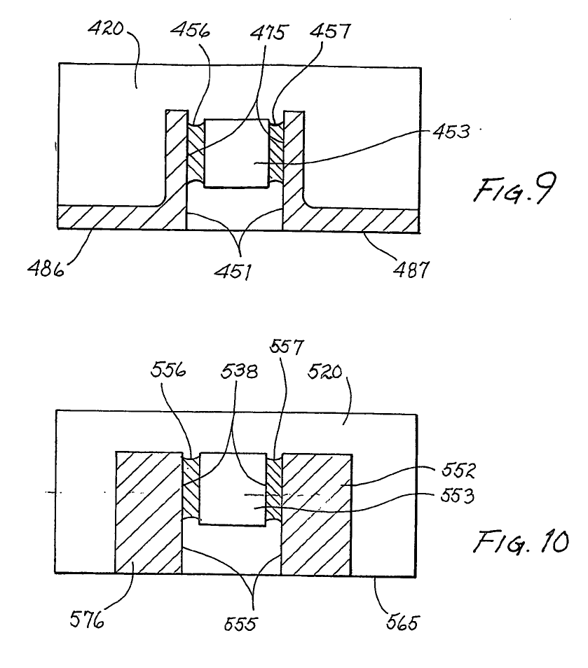

Another embodiment of the invention is shown in FIG. 10 wherein semiconductor device 553 is mounted vertically in molded package 520 between a conductive slug 552 and a conductive slug 576. Semiconductor device 553 is assembled with solder bump 557 attached to conductive slug 552 and solder bump 556 attached to conductive slug 576 using industry standard techniques. An area 555 that will not solder is formed on conductive slug 552 and conductive slug 576. Such an area 555 can be formed using a variety of industry standard techniques with coating referred to as “solder resists” or selective plating of metals that are then oxidized and form the selected areas that will not solder. When semiconductor device 553 is attached with solder bump 557 soldered to conductive slug 552 and solder bump 556 soldered to conductive slug 576, the semiconductor device 553 is aligned with conductive slug 552 by the flow of solder bump 557 to a solderable area 575 of conductive slug 552 and is aligned with conductive slug 576 by the flow of solder bump 556 to a solderable area 575 of conductive slug 576. Contact area 577 for conductive slug 576 and contact area 565 for conductive slug 552 are flush with the bottom surface 590 of molded package 520.

This invention has several advantages over any current packages. The larger semiconductor device that can be packaged using this invention allows for greater power dissipation while the elimination of the wire used in chip and wire construction improves the high frequency performance of any packaged device by reducing the inductance associated with the wire used in the chip and wire assembly. The lower height possible with this invention improves handling of the packaged device thereby reducing the costs associated with such handling while the elimination of any leads extending beyond the package body further improves handling characteristics lowering costs even more. The flexibility of this invention with various shapes of the conductive leads results in the ability to accommodate a variety of discrete semiconductor devices with solderable contacts on one side of the device or on both sides of the device. Further both rectangular and square shaped discrete semiconductor devices can be packaged using this invention.

What is claimed is:

1. A small outline leadless package comprising:
(a) a molding compound encapsulating discrete semiconductor devices comprising one of a solder contact bump small outline integrated circuit and a solder contact bump small outline transistor to form a package having a top, bottom, and four side surfaces;
(b) a pair of electrical contacts each contacting a solder contact bump and extending to and flush with one of said surfaces;
(c) each of said electrical contacts providing an exposed contact surface co-planar with said one of said surfaces and terminating at a junction between said one of said surfaces and another of said surfaces; and
(d) the termination of said contacts occurring only at oppositely disposed package surfaces.

2. The combination set forth in claim 1 wherein said one of said surface is a top or bottom surface and said another of said surfaces is a side surface.

3. The combination set forth in claim 1 wherein each of said electrical contacts include longitudinally extending notches.

4. The combination set forth in claim 1 wherein the exposed contact surface of said electrical contacts is shaped to identify the electrical function of the encapsulated device.

5. The combination set forth in claim 1 wherein one of said electrical contacts is S-shaped for contacting solder bumps on a surface of said discrete semiconductor device and wherein a second electrical contact is planar and contacts solder contact bumps on an opposite side of said discrete semiconductor device.

6. A small outline leadless package comprising:
(a) a molding compound encapsulating discrete semiconductor devices comprising one of a solder contact bump small outline integrated circuit solder contact bump small outline transistor to form a package having top, bottom and four side surfaces;
(b) a pair of S-shaped electrical contacts each contacting a solder contact bump and extending to and flush with one of said surfaces, said electrical contacts contacting solder bumps on a top surface of the encapsulated device and extending to a bottom surface of said package;
(c) each of said electrical contacts providing an exposed contact surface coplanar with one of said package surfaces and terminating at a junction between said one of said package surfaces and another of said package surfaces; and
(d) the termination of said contacts occurring only at oppositely disposed package surfaces.

7. The small outline leadless package of claim 6 wherein said one of said surfaces is a bottom package surface and another of said surfaces is a side package surface.

8. A small outline leadless package comprising:
(a) a molding compound encapsulated discrete semiconductor device comprising one of a solder contact bump small outline integrated circuit and a solder contact bump small outline transistor to form a package having a top, bottom and four side surfaces;
(b) a pair of L-shaped electrical contacts each contacting a solder contact bump and extending to and flush with two of said package surfaces;
(c) said electrical contacts providing an exposed contact surface coplanar with each of said two package surfaces and terminating at a junction between said two package surfaces; and
(d) the termination of said contacts occurring only at oppositely disposed package surfaces.

9. The small outline leadless package of claim 8 wherein said discrete semiconductor device is mounted between two vertically extending legs of opposing L-shaped electrical conductors.
